(19) United States
(12) Patent Application Publication
(10) Pub. No.: US 2020/0267875 A1
(43) Pub. Date: Aug. 20, 2020

(54) ELECTRONIC APPARATUS HAVING NOISE SUPPRESSION MECHANISM

(71) Applicant: Realtek Semiconductor Corporation, Hsinchu (TW)

(72) Inventors: Hao-Wei CHAN, Taichung (TW); Ruey-Beei WU, Taipei (TW); Shih-Hung WANG, Hsinchu (TW); Wen-Shan WANG, Hsinchu (TW)

(21) Appl. No.: 16/790,884

(22) Filed: Feb. 14, 2020

(30) Foreign Application Priority Data
Feb. 15, 2019 (TW) 108105195

(51) Int. Cl. H05K 9/00; H01L 23/552; H05K 1/02; H05K 7/20; H04B 15/02

(52) U.S. Cl. CPC H05K 9/0024; H01L 23/552; H05K 1/0218; H05K 9/0039; H05K 2201/10431; H04B 15/02; H05K 2201/0707; H05K 2201/09818; H05K 7/2039

(57) ABSTRACT

An electronic apparatus having noise suppression mechanism is provided that includes a circuit board, a wireless communication circuit, a digital signal generation circuit, a metal shield and a grounding metal pillar. The wireless communication circuit is disposed on a chip disposing area of the circuit board and performs wireless communication within a wireless signal frequency range. The digital signal generation circuit is disposed on the chip disposing area and generates a digital signal transmitted through a transmission path within the chip disposing area. The metal shield is coupled to the circuit board to cover the chip disposing area. The grounding metal pillar is disposed on the chip disposing area of the circuit board. The grounding metal pillar extends for contacting the metal shield and increases a resonant frequency of the metal shield.

### RELATED APPLICATIONS

This application claims priority to Taiwan Application Serial Number 108105195, filed Feb. 15, 2019, which is herein incorporated by reference.

### BACKGROUND

### Field of Invention

The present invention relates to a noise suppression technology. More particularly, the present invention relates to an electronic apparatus having a noise suppression mechanism.

### Description of Related Art

In some electronic devices, a metal shielding case is disposed at an area having chips disposed thereon to prevent the radiation. However, when digital signals are transmitted in the chips, the shielding case forms a transmission path for the noise due to the resonance. The noise generated due to the existence of the shielding case causes interference to other modules, e.g. radio frequency communication circuit.

Accordingly, what is needed is an electronic apparatus having a noise suppression mechanism to address the issues mentioned above.

### SUMMARY

An aspect of the present invention is to provide an electronic apparatus having noise suppression mechanism that includes a circuit board, a wireless communication circuit, a digital signal generation circuit, a metal shield and at least one grounding metal pillar. The wireless communication circuit is disposed on a chip disposing area of the circuit board and is configured to perform wireless communication within a wireless signal frequency range. The digital signal generation circuit is disposed on the chip disposing area of the circuit board and is configured to generate a digital signal that is transmitted through at least one transmission path within the chip disposing area. The metal shield is coupled to the circuit board to cover the chip disposing area. The grounding metal pillar is disposed on the chip disposing area of the circuit board. The grounding metal pillar extends for contacting the metal shield and is configured to increase a resonant frequency of the metal shield such that a noise value related to a noise of the digital signal coupled with the metal shield is smaller than an interference threshold value.

These and other features, aspects, and advantages of the present invention will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1A is a block diagram of a three-dimensional perspective diagram of an electronic apparatus having noise suppression mechanism in an embodiment of the present invention;

FIG. 1B is diagram of a cross-sectional side view of the electronic apparatus along the A direction in FIG. 1A in an embodiment of the present invention;

FIG. 2A is a waveform diagram of the digital signal on a time domain in an embodiment of the present invention;

FIG. 2B is a waveform diagram of energy spectrum of the digital signal in an embodiment of the present invention;

FIG. 3 is a diagram of the frequency response of the digital signal resonating with the metal shield in an embodiment of the present invention; and

FIG. 4 is pattern of the effect on the resonant frequency, in which the position of the grounding metal pillar acts as the center, in an embodiment of the present invention.

### DETAILED DESCRIPTION

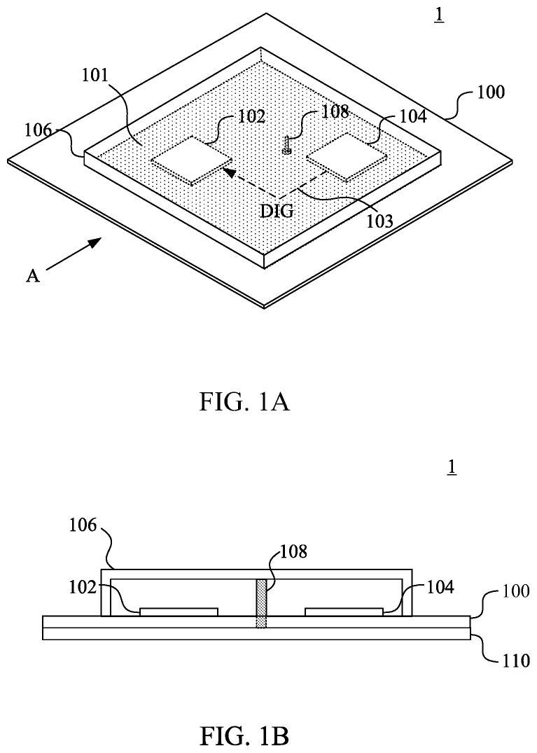

Reference is made to FIG. 1A and FIG. 1B. FIG. 1A is a block diagram of a three-dimensional perspective diagram of an electronic apparatus 1 having noise suppression mechanism in an embodiment of the present invention. FIG. 1B is diagram of a cross-sectional side view of the electronic apparatus 1 along the A direction in FIG. 1A in an embodiment of the present invention.

The electronic apparatus 1 includes a circuit board 100, a wireless communication circuit 102, a digital signal generation circuit 104, a metal shield 106 and a grounding metal pillar 108.

In an embodiment, the circuit board 100 includes a chip disposing area 101 configured to dispose different chip modules, such as but not limited to the wireless communication circuit 102 and the digital signal generation circuit 104 to provide different functions. In different embodiments, a processing circuit, a digital to analog conversion circuit, an analog to digital conversion circuit or other functional circuits (not illustrated) may be disposed in the chip disposing area 101. In an embodiment, the chip disposing area 101 may include a wire 103 configured to electronically couple different circuits in the chip disposing area 101 to provide a transmission path for signals.

The wireless communication circuit 102 is disposed on the chip disposing area 101 and is configured to perform wireless communication within a wireless signal frequency range. In an embodiment, the wireless communication circuit 102 is a frequency radio circuit and the wireless signal frequency range is a frequency radio range, such as, but not limited to frequency ranges having a central frequency of 2.4 GHz or 5 GHz.

The digital signal generation circuit 104 is disposed on the chip disposing area 101 of the circuit board 100 and is configured to generate a digital signal DIG that is transmitted through at least one transmission path within the chip disposing area 101. In an embodiment, the digital signal generation circuit 104 is a clock signal generation circuit and the digital signal DIG is a digital clock signal. In another embodiment, the digital signal generation circuit 104 is a data signal generation circuit and the digital signal DIG is a digital data signal. The digital signal generation circuit 104 can transmit the digital signal DIG through the wire 103 to the wireless communication circuit 102 or through other wires to other circuits within the chip disposing area 101.

The metal shield 106 is coupled to the circuit board 100 to cover the chip disposing area 101. More specifically, the metal shield 106 acts as a shield cover to cover the chip disposing area 101 to provide an electromagnetic interference (EMI) prevention and a heat-dissipating mechanism.

The grounding metal pillar 108 is disposed on the chip disposing area 101 of the circuit board 100. The grounding metal pillar 108 extends for contacting the metal shield 106. In an embodiment, the grounding metal pillar 108 can selectively penetrate through the metal shield 106.

In an embodiment, the grounding metal pillar 108 is grounded through a grounding path of the circuit board 100. For example, a grounding wire can be disposed within the chip disposing area 101 of the circuit board 100 such that the grounding metal pillar 108 is grounded through the grounding wire. In another embodiment, a grounding board 110 is disposed at a side of the circuit board 100 opposite to the side corresponding to the chip disposing area 101, as illustrated in FIG. 1B. The grounding metal pillar 108 can be disposed to penetrate through the circuit board 100 and contact the grounding board 110 to be grounded through the grounding board 110.

The grounding metal pillar 108 is configured to increase a resonant frequency of the metal shield 106 such that a noise value related to a noise of the digital signal DIG coupled with the metal shield 106 is smaller than an interference threshold value.

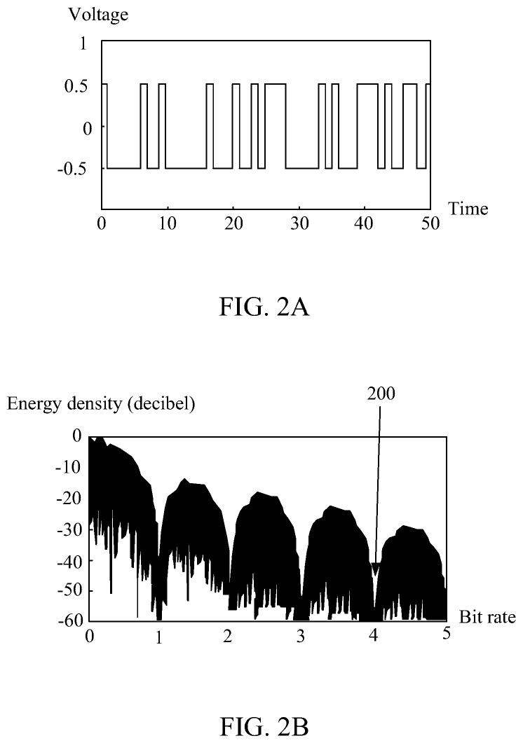

Reference is now made to FIG. 2A and FIG. 2B. FIG. 2A is a waveform diagram of the digital signal DIG on a time domain in an embodiment of the present invention. In FIG. 2A, the X-axis represents times and the Y-axis represents the voltage values. In an embodiment, the digital signal DIG in FIG. 2A is generated based on random appearing of 0 and 1. FIG. 2B is a waveform diagram of energy spectrum of the digital signal DIG in an embodiment of the present invention. In FIG. 2B, the X-axis is the bit rate that is transformed to an integer multiplication and the Y-axis is the normalized energy density having the unit of decibel. In an embodiment, the waveform in FIG. 2B is generated by using pseudo-random binary sequence (PRBS) and Fourier transform.

In an embodiment, the grounding metal pillar 108 is configured to increase the resonant frequency of the metal shield 106 to be larger than the wireless signal frequency range and a value corresponds to a valley point of the waveform of the energy spectrum of the digital signal DIG, e.g. the valley point 200 in FIG. 2B. In an embodiment, each of the valley points of the waveform of the energy spectrum of the digital signal DIG corresponds to a location of an integer multiplication of the clock that is used to operate the digital signal generation circuit 104.

When the grounding metal pillar 108 moves the resonant frequency to the corresponding valley point, the digital signal DIG is coupled to the metal shield 106 and generates a relatively small amount of energy. As a result, the noise is not able to be amplified by the metal shield 106. More specifically, through the noise is still generated by the digital signal DIG, the transmission path is suppressed and the effect of the noise on the wireless communication circuit 102 operated within the wireless signal frequency range is greatly reduced.

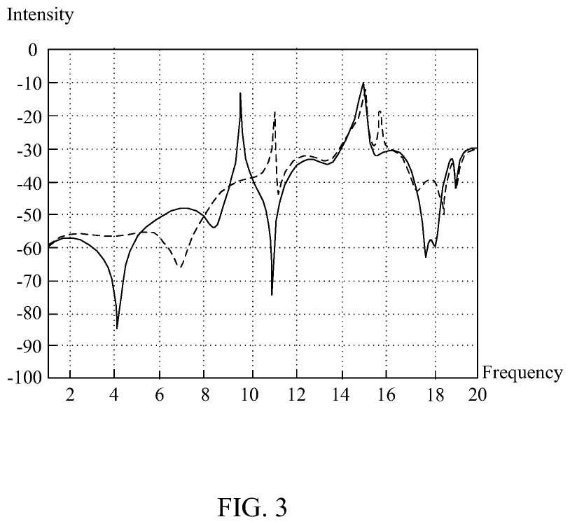

Reference is now made to FIG. 3. FIG. 3 is a diagram of the frequency response of the digital signal DIG resonating with the metal shield 106 in an embodiment of the present invention. In FIG. 3, the X-axis represents frequency having the unit of GHz and the Y-axis represents intensity having the unit of decibel. The solid line represents the frequency response waveform when the grounding metal pillar 108 is absent. The dashed line represents the frequency response waveform when the grounding metal pillar 108 is present.

In an embodiment, the clock frequency of the digital signal DIG is such as, but not limited to 2.7 Gbps. As illustrated in FIG. 3, when the grounding metal pillar 108 is absent, the maximal resonant frequency is at 9.3 GHz. When the resonant frequency is required to be moved to the valley point 200 (the fourth node) in FIG. 2B, the grounding metal pillar 108 has to move the maximal resonant frequency to 10.8 GHz.

Reference is now made to Table 1. Table 1 is the values of measured noise and square root values of the noise under the conditions of the absence of the metal shield 106 on the circuit board 100, the presence of the metal shield 106 on the circuit board 100 and the presence of the metal shield 106 and the disposition of the grounding metal pillar 108 on the circuit board 100 in an embodiment of the present invention. In an embodiment, the unit of the values in Table 1 is millivolt.

| Condition | Maximal noise | Square root noise |
|---|---|---|
| Absence of metal shield | 13.5 | 2.5 |
| Presence of metal shield | 18.7 | 5.2 |
| Presence of metal shield | 12.5 | 3.4 |
| and disposition of | | |
| grounding metal pillar | | |

Based on Table 1, when the metal shield 106 is presented and the grounding metal pillar 108 is not disposed, the noise caused by the digital signal DIG is larger than the noise under the condition that the metal shield 106 is absent due to the coupling effect of the metal shield 106. However, after disposing the grounding metal pillar 108, the coupling effect of the metal shield 106 is reduced due to the increase of the resonant frequency. The noise caused by the digital signal DIG is therefore reduced.

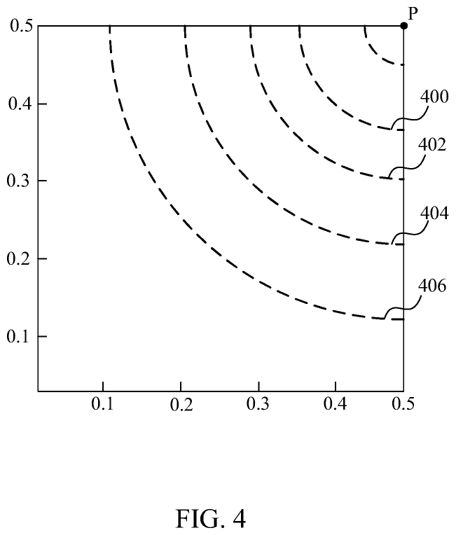

Reference is now made to FIG. 4. FIG. 4 is pattern of the effect on the resonant frequency, in which the position P of the grounding metal pillar 108 acts as the center, in an embodiment of the present invention. The X-axis and the Y-axis represent the relative ratio among different positions.

As illustrated in FIG. 4, the distribution of the sections 400, 402, 404 and 406 is similar to a topographic map, in which the position P is a center. The position P of the grounding metal pillar 108 can increase the resonant frequency to such as, but not limited to 1.25 times of the original value. The sections 400, 402, 404 and 406 respectively increase the resonant frequency to such as, but not limited to 1.2, 1.15, 1.1 and 1.05 times of the original value. As a result, if the resonant frequency is desired to be moved from 9.3 GHz to 10.8 GHz, in which 1.16 times of the original values is desired to be achieve, the relative position of the path that the digital signal DIG passing through, e.g. the wire 103 in FIG. 1A and the grounding metal pillar 108 can be disposed based on the relation of the section 402 and the position P according to the distribution of the pattern in FIG. 4.

In an embodiment, the grounding metal pillar 108 is not necessary to move the resonant frequency to the position corresponding to the valley point of the energy spectrum waveform of the digital signal DIG. The resonant frequency of the metal shield 106 is only required to be moved to a position in which a noise value related to the noise of the digital signal DIG is smaller than an interference threshold value.

In an embodiment, in order to evenly reduce the effect of the noise on the wire within the chip disposing area 101, the grounding metal pillar 108 can be disposed in a central region of the chip disposing area 101.

By disposing the grounding metal pillar 108, the electronic apparatus 1 of the present invention can suppress the noise caused by the digital signal DIG through the metal shield 106 to avoid the interference to the wireless communication circuit 102 of the electronic apparatus 1.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electronic apparatus having noise suppression mechanism, comprising:
a circuit board;
a wireless communication circuit disposed on a chip disposing area of the circuit board and configured to perform wireless communication within a wireless signal frequency range;
a digital signal generation circuit disposed on the chip disposing area of the circuit board and configured to generate a digital signal that is transmitted through at least one transmission path within the chip disposing area;
a metal shield coupled to the circuit board to cover the chip disposing area; and
at least one grounding metal pillar disposed on the chip disposing area of the circuit board, wherein the at least one grounding metal pillar extends for contacting the metal shield and is configured to increase a resonant frequency of the metal shield such that a noise value related to a noise of the digital signal coupled with the metal shield is smaller than an interference threshold value.

2. The electronic apparatus of claim 1, wherein the wireless communication circuit is a radio frequency communication circuit, and the wireless signal frequency range is the radio frequency range.

3. The electronic apparatus of claim 1, wherein the grounding metal pillar is disposed in a central region of the chip disposing area.

4. The electronic apparatus of claim 1, wherein the grounding metal pillar is disposed to penetrate through the metal shield.

5. The electronic apparatus of claim 1, wherein the grounding metal pillar is disposed to be grounded through a grounding path of the circuit board.

6. The electronic apparatus of claim 1, wherein the grounding metal pillar is disposed to penetrate through the metal shield and is grounded through a ground board.

7. The electronic apparatus of claim 1, wherein the grounding metal pillar is disposed to move the resonant frequency of the metal shield to a valley point of a waveform of an energy spectrum of the digital signal.

8. The electronic apparatus of claim 1, wherein the digital signal is a clock signal or a data signal.

9. The electronic apparatus of claim 8, wherein a valley point of a waveform of an energy spectrum of the digital signal corresponds to a location of an integer times of a clock signal.

10. The electronic apparatus of claim 1, wherein the metal shield provides an electromagnetic interference prevention and a heat-dissipating mechanism.
